(19) United States
(12) Patent Application Publication
(10) Pub. No.: US 2002/0170678 A1
(43) Pub. Date: Nov. 21, 2002

(54) Plasma processing apparatus

(76) Inventors: Toshio Hayashi, Chigasaki-shi (JP); Wei Chen, Andover, MA (US); Kippei Sugita, Cambridge, MA (US); Kouji Kaga, Tsushima-shi (JP)

Correspondence Address: BIERMAN MUSERLIAN AND LUCAS, 600 THIRD AVENUE, NEW YORK, NY, 10016

(21) Appl. No.: 10/146,366

(22) Filed: May 15, 2002

(30) Foreign Application Priority Data
May 18, 2001 (JP) 2001-149825
Oct. 1, 2001 (JP) 2001-305101

(51) Int. Cl. C23F 1/00; C23C 16/00; B05C 11/00

(52) U.S. Cl. 156/345.48; 118/723 I; 156/345.28; 118/712

(57) ABSTRACT

The present invention is to provide a plasma processing apparatus, whose structure can be simplified, and further, which is capable of forming highly effective plasma and obtaining a satisfactory vertical etching property without involving a problem concerning interference. In the plasma processing apparatus according to the invention, a ground electrode provided at a position opposite to a substrate mounting electrode is configured to be a counter electrode, whose potential is in a floating state, and radio frequency power is branched at an arbitrary position of the radio frequency antenna coil, which generates inductive discharge, into the counter electrode through a capacitor so as to share a part of the radio frequency power used for inductive discharge, thereby generating a self-bias in the counter electrode. In the system, there is provided a mechanism for controlling the radio frequency voltage to be applied to the floating electrode uniformly.

### BACKGROUND OF THE INVENTION

1. (Field of the Invention)

The present invention relates to a plasma processing apparatus, in particular, an etching apparatus that etches a thin film formed on a semiconductor substrate such as silicon or the like, materials for electronic devices, various glass, or various dielectrics, etc. with use of plasma.

2. (Prior Art)

In an etching apparatus in which gas is introduced into a vacuum chamber so as to form inductively coupled discharge plasma by radio frequency and a radio frequency power is applied to an electrode on which a substrate is mounted so as to generate a negative self-bias on the substrate mounting electrode, the inventors of the present applipositive ions have proposed that a ground electrode is provided at the position opposite to the substrate mounting electrode.

One example of such conventional etching apparatuses is disclosed in the Japanese Patent Application Laid-Open Publication No. 7-263192. FIG. 1 of the accompany drawings shows a schematic structure of the magnetic neutral loop discharge etching apparatus disclosed in this Publication. As shown in FIG. 1, this etching apparatus has a vacuum chamber 1. An upper section of the chamber is a plasma generating section 2, and a lower section thereof is a substrate mounting electrode section 3. The plasma generating section 2 includes a cylindrical dielectric wall 4. The substrate mounting electrode section 3 is connected to an evacuating system 5. Three magnetic coils 6, 7 and 8 are provided outside the dielectric wall 4 for forming an annular magnetic neutral line or loop 9 in the plasma generating section 2. A radio frequency antenna coil 10 is disposed between the intermediate magnetic coil 7 and the outside of the dielectric wall 4, and is used for generating plasma. The radio frequency antenna coil 10 is connected to a radio frequency power supply 11 and configured to apply an alternating electric field along the magnetic neutral loop 9 formed by the magnetic coils 6, 7 and 8 so as to generate discharge plasma on the relevant magnetic neutral loop 9.

A substrate mounting electrode 12 is provided in parallel to the magnetic neutral loop 9 with an insulating member 13 interposed in the substrate mounting electrode section 3 of the chamber 1. The substrate mounting electrode 12 is connected through a blocking capacitor 14 to a radio frequency power supply 15 that applies radio frequency bias power. The potential of the substrate mounting electrode 12 is turned into a floating state by the blocking capacitor 14 so that the relevant electrode becomes a floating electrode having a negative bias potential. A top plate 16 of the plasma generating section 2 is bonded in a sealed manner to an upper flange of the dielectric wall 4, and formed as an opposite electrode. In the plasma generating section 2, there is provided a gas inlet 17 through which etching gas is introduced into the vacuum chamber 1. Although it is not shown in FIG. 1, the gas inlet 17 is connected to a supply source of etching gas through a gas supply path and a mass flow controller that controls quantity of etching gas flow. The evacuating port 5 is provided in the substrate mounting electrode section 3.

In the case of the magnetic neutral loop discharge etching apparatus shown in FIG. 1, there has been a problem in that, when the relevant system is employed to etch a resist pattern having a fine structure with use of halogen etching gas, the film deposited on the inner face of the top plate exfoliates by etching for a long time, thereby generating dust.

Meanwhile in regard to etching a material of a substrate is etched by irradiating good reactive radicals and ions to the substrate and gasifying the material of the substrate by reaction to irradiated radicals and ions. However, the etching cannot be carried out satisfactorily by simply chipping. With the evolution of micro-patterning, importance of shape control has been increased.

For that reason, it is necessary to generate not only an etchant but also another material, which sticks to an inner wall of a micropore so as to protect the wall to which no ions are irradiated, in plasma. In micro-patterning in width of 0.3 μm or less, the relative density of the etchant and the protective material and the relative carry-over quantity of those materials into the micropore are important. In the case where the quantity of the protective material exceeds one of the etchant too much, a micropore of 0.3 μm or less in width is filled with the protective material. That is, so-called the etch-stop occurs, and therefore the etching cannot be carried out. On the contrary, in the case where the protective material is far too little than the etchant, the wall is eroded by the etchant. As a result, bowing occurs on the wall so that the desirable shape cannot be obtained.

In the conventional etching apparatus proposed in the past, radio frequency power is applied to an antenna used for generating plasma and an electrode used for generating bias voltage, which is electrically in a floating state. When halogen gas is introduced into an etching chamber and then plasma is formed therein, gas molecule is decomposed by means of plasma. Then, an etchant or a material that easily polymerizes is produced. On reaching the substrate mounting electrode, the easily polymerizing material acts as a protective material. However, if the easily polymerizing material reaches the wall of a discharge chamber, the relevant material adheres to the wall and causes dust.

Charge-up in a micropore can be considered as one of the mechanisms of etch-stop generation. In the system, the substrate bias is in a negative state, so that ions and radicals come flying into the pore. Then, etching progresses with ion assist. If the pore is of very small size, electrons do not sufficiently flow into the pore due to a sheath electric field. Therefore, a charge in the pore cannot be corrected and positive charge-up occurs. As a result, positive ions are prevented from flowing into the pore and thus etching cannot progress satisfactorily.

For that reason, the inventors of the present application have proposed an etching apparatus, in which gas is introduced into a vacuum chamber so as to form inductively coupled discharge plasma by radio frequency, a radio frequency power is applied to a substrate mounting electrode, thereby generating a negative self-bias in the relevant substrate mounting electrode, a ground electrode provided at the position opposite to the substrate mounting electrode is arranged as an opposite electrode whose potential is in a floating state by a dielectric, and the opposite floating electrode is supplied with power from the third radio frequency power supply. (See the Japanese Patent Application Laid-Open Publication No. 9-123897.)

An example of such reactive ion etching apparatus using three individual radio frequency power supplies is shown in the accompanying drawing, FIG. 2. In the etching apparatus shown in FIG. 2, the reference character 1 denotes a vacuum chamber. The vacuum chamber 1 comprises a plasma generating section 2 located at the upper portion thereof and a substrate mounting electrode section 3. The plasma generating section 2 includes a cylindrical dielectric wall 4. The substrate mounting electrode section 3 is connected to an exhaust system 4. Three magnetic coils 6, 7 and 8 are provided outside the dielectric wall for forming a magnetic neutral loop in the plasma generating section 2 of the vacuum chamber 1.

A radio frequency coil 10 is disposed between the intermediate magnetic coil 7 and the outside of the dielectric wall 4 for generating plasma, and connected to a radio frequency power supply 11. The radio frequency coil 10 applies an alternating electric field along the magnetic neutral loop 9, which is formed in the upper plasma generating section 2 of the vacuum chamber 1 by the magnetic coils 6, 7 and 8, so as to generate discharge plasma on the relevant magnetic neutral loop 9.

A substrate mounting electrode 12 is provided parallel to a plane where includes the magnetic neutral loop 9 in the plasma generating section 2 of the vacuum chamber 1, in the substrate mounting electrode section located below with an insulating member 13 interposed. The substrate mounting electrode 12 is connected through a blocking capacitor 14 to a radio frequency power supply 15 that is a RF bias source. In a top plate 16 of the plasma generating section 2 of the vacuum chamber 1, there is provided a gas inlet 17 through which etching gas is introduced into the vacuum chamber 1.

The top plate 16 of the plasma generating section 2 of the vacuum chamber 1 is bonded in a sealed manner to an upper flange of the dielectric wall 4 with an insulator 18 interposed therebetween. The top plate 16 is formed as an opposite electrode and connected to a radio frequency bias power supply 19. Further, the top plate 16 is applied with a weak radio frequency bias and functions as a floating electrode.

As described above, the opposite electrode, substrate mounting electrode and the antenna are supplied with radio frequency power. Therefore, there can be expected advantages that it enables suppression of film adhering to the surface of the opposite electrode, generation of plasma by means of the opposite electrode, electron supply to the substrate and the like. Meanwhile, in regard to an ICP plasma source and an ECR plasma source, a problem lies in that a material generated by decomposing gas by means of plasma adheres to the wall and the adhered material exfoliates before long and falls down on the surface of the substrate as dust. However, in the apparatus wherein the opposite electrode is provided above the substrate and radio frequency power is applied thereto, ions included in plasma continuously sputter the surface of the opposite electrode. Therefore, film-sticking or adhering can be suppressed and thus dust can be prevented from occurring. In addition to that, by sputtering the film stuck to the top plate, i.e., the internal surface of the opposite electrode and polymerized, a secondary effect can be expected in that an etchant is generated.

However, in that case, three aforementioned radio frequency power supplies, i.e., the radio frequency power supply used for inductively coupled discharge, radio frequency power supply used for opposite electrode and radio frequency power supply used for substrate mounting electrode are required. Furthermore, a problem arises in that, since the opposite electrode and the antenna coil are disposed close to each other, radio frequency electric fields to be applied thereto interfere with each other. This matter of interference can be avoided by applying power at different frequencies, respectively, or performing phase control. However, the interfering condition differs in accordance with pressure, kinds of gas to be used or discharge power. Therefore, it has been required to perform the phase control so as to prevent interferences from occurring every time when the operation condition is changed.

A similar magnetic neutral loop discharge etching apparatus is also disclosed in the Japanese Patent Application Laid-Open Publication ions No. 10-317173.

In the case of the conventional magnetic neutral loop discharge etching apparatuses disclosed in the Japanese Patent Application Laid-Open Publication Nos. 9-123897 and 10-317173, undesirable adhesion of film sticking to the inner wall of the vacuum chamber is suppressed to the minimum extent and thus dust is also restrained from occurring from the inner wall portion of the top plate. Further, the etching resistance of a mask is then improved. However, three radio frequency power sources are required in this case and therefore the system becomes expensive. In addition to that, another problem arises, that is, since the opposite electrode (floating electrode) and the induction coil are disposed close to each other, radio frequency magnetic fields to be applied to both the opposite electrode and the induction coil interfere with each other. On the other hand, assume the case where the feed line from the radio frequency power supply that is connected to the radio frequency antenna coil is branched, and radio frequency power is separately applied to a Faraday shield-like floating electrode disposed to the top plate or inside the antenna coil through the capacitor provided on the shunt. In this case, the system can be inexpensive. However, the supply of electric power depends on the capacity of the capacitor and the electric power of the antenna coil. Therefore, the system cannot be controlled sufficiently.

FIG. 3 shows a schematic structure of a magnetic neutral loop discharge etching apparatus disclosed in the Patent Application No. 2001-149825. In FIG. 3, the same constituting elements as those of the conventional example shown in FIGS. 1 and 2 are indicated by the same reference numerals and the detailed descriptions for those elements will be omitted.

The etching apparatus shown in FIG. 3 employs a two-frequency discharge method that is a modification of the aforementioned three-frequency discharge method. In this etching apparatus, a ground electrode provided at the position opposite to the substrate mounting electrode 12 is an opposite electrode whose potential is in a floating state by a dielectric so as to apply weak radio frequency bias power to the opposite electrode (top plate 16). Further, in this etching apparatus, a shunt is provided at an arbitrary position of a feed line from the radio frequency power supply 11 used for generating plasma to the radio frequency antenna coil 10 that generates inductive discharge, and a part of radio frequency power for inductive discharge is branched and applied to the opposite electrode through a capacitor provided on the shunt, thereby making the counter electrode generate a self-bias. The top plate 16 serving as an opposite electrode functions as a floating electrode.

As mentioned in the above, in a conventional etching apparatus having an inductive coupling type of plasma source, there has been a problem in that an introduced gas molecule is decomposed by means of plasma and the decomposed materials stick to an inner wall of a chamber or in that etched products stick to the inner wall. Therefore, the adhesion has been prevented from occurring by setting the entire chamber at a high temperature, or providing a heating antisticking (shield)plate on the wall of the chamber, etc.

In the conventional art described above, however, there has been a problem in that the method of heating the entire vacuum chamber so as to set the entire chamber at a high temperature requires a large-scale system and thus electric power is consumed largely. On the other hand, the method of using a heating antisticking (shield) plate is performed with the antisticking plates mounted at portions where films sticks relatively harsh. However, the film sticking to the antisticking plates becomes thick with lapse of time. Then, the stuck film exfoliates before long, which causes dust. Accordingly, it is required that the antisticking plates are dismounted regularly for cleaning.

In regard to the magnetic neutral loop discharge etching apparatus (shown in FIG. 3) disclosed in the Patent Application No. 2001-149825, dust is restrained from occurring, and further the etching resistance of the mask is improved. Thus, it is possible to carry out deep-trench quartz etching to the extent of 30 to 40 μm. However, as the power of the antenna coil is increased or decreased, a problem arises in that the radio frequency power to be applied to the top plate (opposite electrode) is also increased or decreased. In order to eliminate the film stuck to the top plate by a sputter-etching processing, it is necessary that radio frequency voltage having a certain value or more is applied to the top plate. However, if the voltage is too high, a problem arises as follows. In this case, the resistance of the mask is improved. However, the sputtering effect is too strong, so the sputtered materials come flying to an etching section. Therefore, an etching processing is restrained and thus the etching rate is reduced.

The magnetic neutral loop discharge etching apparatus disclosed in the Japanese Patent Application Laid-Open Publication No. 10-317173 pertains to a three-frequency discharge method for an etching apparatus. This method is configured in that, in addition to the structure of the etching apparatus shown in FIG. 2, the top plate is bonded in a sealed manner to the upper flange of the wall (dielectric wall) of the plasma generating section with an insulating member interposed so as to oppose to the substrate mounting electrode, and a radio frequency bias power supply is connected to the top plate through a capacitor so as to apply a weak bias to the top plate. The top plate serving as an opposite electrode functions as a floating electrode. In this manner, the relevant system is configured to apply a radio frequency power to the counter electrode, the substrate mounting electrode and the plasma generating antenna coil.

It is therefore an object of the present invention to provide a plasma processing apparatus, with which the aforementioned problems in the conventional art can be solved, and whose structure can be simplified, and further, which is capable of forming highly effective plasma and obtaining the satisfactory vertical etching property without involving a problem concerning interference.

Another object of the present invention is to provide a plasma processing apparatus of two-frequency type discharge system, which has a simple structure and inexpensive, is to be capable of forming highly effective plasma without involving any problem such that radio frequency electric fields to be applied interfere with each other, is configured to apply radio frequency voltage having a predetermined voltage value, and is capable of improving resistance of a mask and achieving a satisfactory etching rate.

### SUMMARY OF THE INVENTION

According to one aspect of the present invention, there is provided a plasma processing apparatus in which gas is introduced into a vacuum chamber so as to form inductively coupled discharge plasma by means of at least one radio frequency antenna coil to which a first radio frequency power source is connected, and a substrate mounting electrode is supplied with a radio frequency power from a second radio frequency power source connected thereto so as to generate a negative self-bias in the substrate mounting electrode, wherein a ground electrode is provided at the position opposite to the substrate mounting electrode and is arranged as an opposite electrode whose potential is kept in a floating state by a dielectric material, and a shunt is provided on a feed line between the radio frequency antenna coil and the first radio frequency power source for applying a part of radio frequency power from the radio frequency power source to the opposite electrode through a capacitor connected to the shunt, thereby generating a self-bias in the opposite electrode.

With the structure described above, it is not necessary to provide a radio frequency power supply separately for the opposite electrode, so that the construction of the system can be simplified. In addition to that, the problem concerning interference can be solved. Since radio frequency power is applied to the opposite electrode so as to generate a negative bias in the counter electrode, the opposite electrode is continuously impacted by positive ions. As a result, in comparison with the conventional structure in that the top plate is used as a ground electrode, film-sticking to the top plate is suppressed and thus dust is also restrained from occurring. Further, not only suppressing generation of dust, but it is also possible to generate an etchant by sputtering the film that stuck to the internal surface of the top plate and polymerized. In addition, with use of a top plate made of metal such as Si, WSi or the like, it is possible to generate materials such as SiFx, WFx or the like, and suppress consumption of a mask by depositing these generated materials. That makes it possible to carry out deep-trench etching.

Further, by applying radio frequency power to the opposite electrode, it becomes possible that secondary electrons from the top plate and electrons accelerated by sheath heating come flying to the substrate so as to correct positive charge-up occurred in the micropore.

Further, in the plasma processing system according the invention, the radio frequency antenna coil for generating inductively coupled discharge plasma may comprise a multiple parallel coil including single one. When the system is configured in this manner, satisfactory vertical etching property can be obtained and thus selectivity can be improved.

Furthermore, in the plasma processing system according to the invention, it is preferable that the opposite electrode is constituted by a top plate that is located at the upper portion of a vacuum chamber formed of a dielectric material.

According to another aspect of the present invention, there is provided a plasma processing apparatus comprising:

a vacuum chamber having a plasma generating section in an upper portion thereof and a substrate mounting electrode section in a lower portion thereof;

at least one radio frequency antenna coil for generating plasma provided outside a dielectric wall of the plasma generating section, the antenna coil being connected to a radio frequency power source;

a substrate mounting electrode disposed in the substrate mounting electrode section, the substrate mounting electrode being connected to another radio frequency power source and applied with radio frequency bias power; and

an opposite electrode disposed in the plasma generating section in a manner of opposing to the substrate mounting electrode,

wherein

the opposite electrode is a floating electrode, which is bonded in a sealed manner to an upper flange of the wall of the plasma generating section with an insulator interposed therebetween and whose potential is in a floating state,

a shunt is provided on a feed line between the antenna coil and the radio frequency power source connected to the antenna coil for applying a part of radio frequency power to the floating electrode through a variable capacitor provided on the shunt, and

control means is provided for monitoring radio frequency voltage to be applied to the floating electrode and controlling the radio frequency voltage uniformly.

The apparatus further comprises at least one magnetic coil provided outside the antenna coil, wherein an alternating electric field is applied along an annular magnetic neutral line or loop formed in a plasma generating section by means of the magnetic coil, thereby making the magnetic neutral loop generate discharge plasma.

In the system, the control means may include a radio frequency voltage measuring circuit that measures voltage to be applied from the radio frequency power source to a floating electrode; a DC differential amplifier circuit that detects the difference between the measured voltage and a predetermined voltage value and is provided with a detection circuit that converts the radio frequency into direct current; and a motor driving circuit that drives the variable capacitor in such a manner that the measured voltage becomes to be equal to the predetermined voltage value, wherein the voltage measuring circuit is connected to the floating electrode, the detection and DC differential amplifier circuit is connected to the voltage measuring circuit, the motor driving circuit is incorporated in a variable capacitor and is connected to the detection and DC differential amplifier circuit, and the variable capacitor controls radio frequency voltage uniformly.

According to a further aspect of the present invention there is provided a plasma processing apparatus comprising:

a vacuum chamber having a plasma generating section in an upper portion thereof and a substrate mounting electrode section in a lower portion thereof;

at least one radio frequency antenna coil provided outside a dielectric wall of the plasma generating section for generating plasma, the antenna coil being connected to a radio frequency power source; and

a substrate mounting electrode disposed in the substrate mounting electrode section, the substrate mounting electrode being connected to another radio frequency power source and applied with radio frequency bias power,

wherein

a Faraday shield or a electrostatic field shield type floating electrode is provided inside the antenna coil,

a shunt is provided on a feed line between the antenna coil and the radio frequency power source connected to the antenna coil for applying a part of radio frequency power to the floating electrode through a variable capacitor provided on the shunt, and

control means is provided for monitoring radio frequency voltage to be applied to the floating electrode and controlling the radio frequency voltage uniformly.

The system may also further comprise at least one magnetic coil that is provided outside the antenna coil. The control means may include a radio frequency voltage measuring circuit; a detection and DC differential amplifier circuit, and a motor driving circuit, in the same manner as the above.

With the system configured as the above, it is not necessary to provide a radio frequency power source for the opposite electrode separately. Therefore, the structure can be simplified, which makes the system inexpensive. Furthermore, it is possible to form highly effective plasma without involving any problem such that radio frequency fields to be applied interfere with each other. In addition, radio frequency having a predetermined voltage value can be applied to the opposite electrode through the floating electrode. Therefore, it is possible to improve resistance of a mask and achieve a satisfactory etching rate.

Additionally, there has been a problem, with respect to a ICP plasma source or ECR plasma source, in that materials generated by discomposing gas by means of plasma stick to the wall and the stuck materials fall down to the surface of the substrate as dust. However, an opposite electrode being in a floating state is provided above the substrate and radio frequency power is applied to the opposite electrode. By doing this, ions included in plasma continuously sputter the surface of the opposite electrode. Therefore, a film is prevented from sticking to the wall, thereby preventing dust from occurring. In addition to that, the film that stuck to a top plate, i.e. the opposite electrode and polymerized is sputtered. Therefore, it can be expected to generate an etchant as a secondary effect.

As described above, the apparatus is constructed in that a radio frequency power is applied to the opposite electrode so as to generate a negative bias thereto. Therefore, the opposite electrode is always impacted by positive ions. As a result, a film is prevented from sticking to the top plate in comparison with the system employing the conventional structure in that the top plate is used as a ground potential, thereby restraining dust from occurring from the top plate. Furthermore, with use of the top plate made of metals such as Si, WSi or the like, materials such as SiFx, WFx or the like are generated and accumulated on the mask so as to hold down the consumption of the mask. Thus, it becomes possible to carry out deep-trench etching.

### BRIEF DESCRIPTION OF THE SEVERAL VIEWS OF THE DRAWING

FIG. 1 is a schematic diagram showing a structure of a conventional magnetic neutral loop etching apparatus;

FIG. 2 is a schematic diagram showing another conventional magnetic neutral loop etching apparatus;

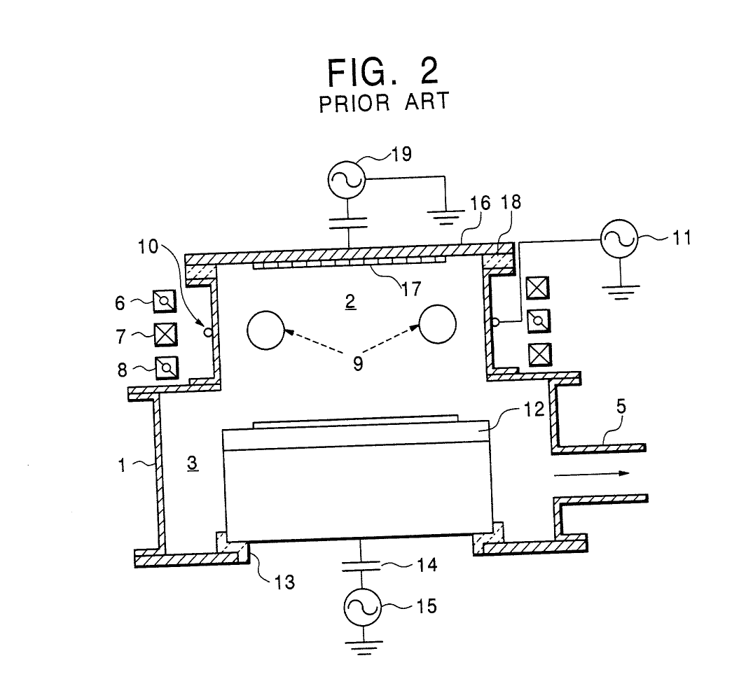

FIG. 3 is a schematic diagram showing a structure of a further conventional etching apparatus;

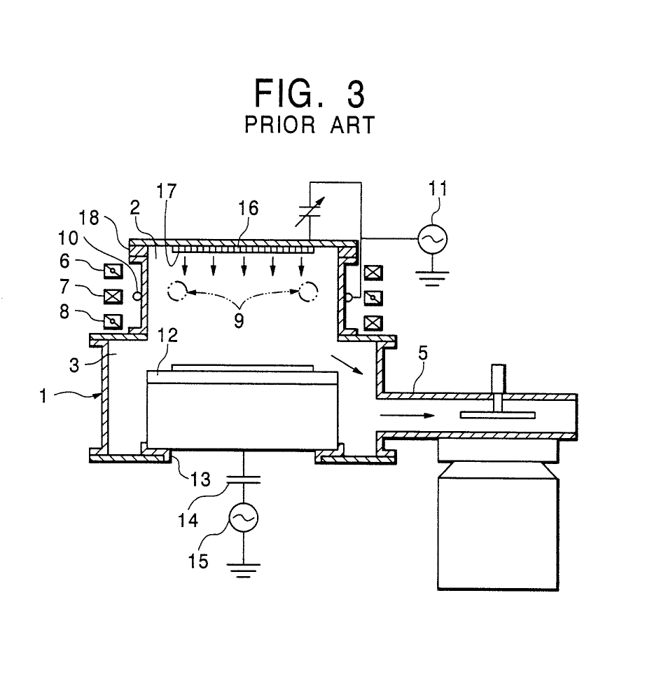

FIG. 4 is a schematic diagram showing one embodiment of the invention;

FIG. 5 is a diagram showing a schematic structure of an etching apparatus according to another embodiment of the invention; and

FIG. 6 is a diagram showing a structure in that a measuring circuit and a control circuit, both provided in the etching apparatus shown in FIG. 5 are incorporated in a variable capacitor.

### DETAILED DESCRIPTION OF THE INVENTION

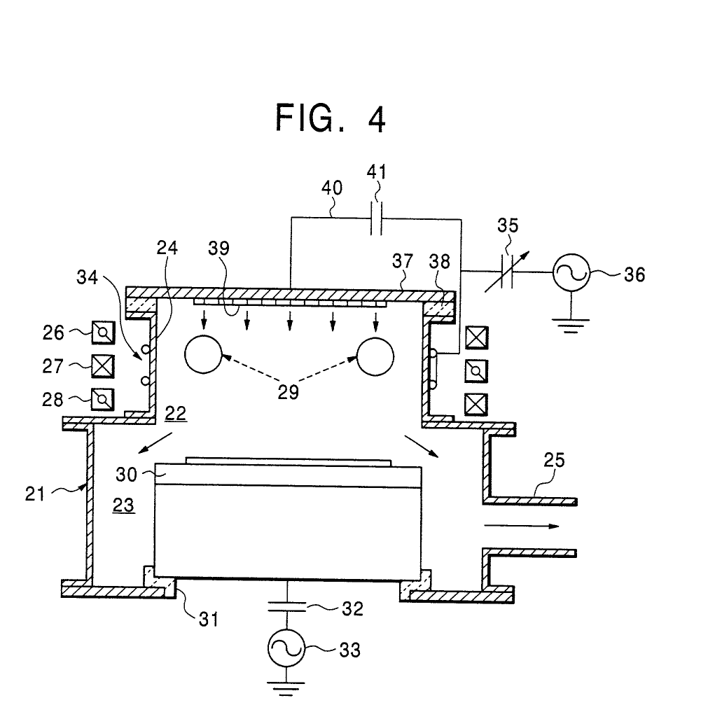

Hereinafter, embodiments of the present invention will be described with reference to FIGS. 4 to 6 of the accompanying drawings.

FIG. 4 shows an embodiment of the etching apparatus according to the invention. The etching apparatus is configured as a two-frequency type of magnetic neutral loop or line discharge etching apparatus. In the etching apparatus shown in FIG. 4, the reference numeral 21 denotes a vacuum chamber, which comprises a plasma generating section 22 in its upper portion and a substrate mounting electrode section 23. The plasma generating section 22 comprises a cylindrical dielectric wall 24. In the substrate mounting electrode section 23, an exhaust port 25 is provided and connected to an appropriate evacuate system not shown.

Three magnetic coils 26, 27 and 28, which constitutes magnetic field generating means for forming a magnetic neutral loop 29 in the vacuum chamber 21, are provided outside the dielectric wall 24. These magnetic coils form the magnetic neutral loop 29 in the plasma generating section 22 located in the upper portion of the vacuum chamber 21. In the lower section of the vacuum chamber 21, a substrate mounting electrode 30 is provided with an insulating member 31 interposed. The substrate mounting electrode 30 is connected through a blocking capacitor 32 to a radio frequency power supply 33 that applies a RF bias to the substrate mounting electrode 30.

Two radio frequency coils 34 used for generating plasma are disposed between the intermediate magnetic coil 27 and the outside of the dielectric wall 24. These radio frequency coils 34 are connected through a variable capacitor 35 to a radio frequency power supply 36. These radio frequency coils 34 add a alternating electric field along the magnetic neutral loop 29 formed by the three magnetic coils 26, 27 and 28 so as to generate discharge plasma on the relevant magnetic neutral loop 29.

The plasma generating section 22 of the vacuum chamber 21 has a top plate 37 that is bonded in a sealed manner to an upper flange of the dielectric wall 24 with an insulator 38 interposed. The top plate 37 is arranged as an opposite electrode. The top plate 37 has an inner wall which is made of carbonic material.

In addition, in the plasma generating section 22 in the upper portion of the vacuum chamber 21, there is provided a gas inlet 39 through which etching gas is introduced into the vacuum chamber 21. Although it is not shown in the drawings, the gas inlet 39 is connected to a supply source of etching gas through a gas supply path and a gas flow rate controller that controls quantity of etching gas flow.

A shunt 40 is provided on a feed line between the antenna coils 34 and the radio frequency power source 36 connected to the antenna coils 34 for applying a part of radio frequency power to the floating electrode through a capacitor 41 provided on the shunt 40. Thus, the branched radio frequency power is applied to the opposite electrode 37 through the capacitor 41 so as to generate a self-bias in the opposite electrode 37.

In the experiment with the etching apparatus configured as described above, etching was performed under the following conditions: the power of radio frequency power source 36 (13.56 MHz) for generating plasma being 2.0 kW; the power of the radio frequency power source 33 (800 kHz) for applying a bias to the substrate mounting electrode 30 being 500 W; and the capacity for the capacitor 41 for branch being 100 pF; Ar 90 sccm (90%) and C₄F₈10 sccm (10%) being introduced into the vacuum chamber 21; and the pressure in the vacuum chamber 21 being in 3 mTorr. Then, it was possible to perform substantially vertical shape etching of 20 μm in depth against a silicon oxide film without any etch-stop.

In the etching with use of the system having the conventional structure under the same conditions as the above, although there were some variance depending on the pattern widths, a mask exhausted at about 15 μm in depth and it was not possible to perform etching deeper than that.

As the materials that stick to the wall surface of the vacuum chamber 21, there are a compound of CF, CF₂, CF₃, C₂F₂, C₂F₄, C₂F₅, C₃F₅, or C₃F₆, etc., and a compound, which has been rather decomposed, of C₂Fₓ, C₃Fₓ, or C₄Fₓ. etc., (x=1 to 2). These compounds stick to the wall surface and form a polymerized film. Without an ion bombardment, the polymerized film formed of these compounds become a thick film and exfoliate before long, thereby generating dust. On the contrary, if there is an ion bombardment, the polymerized film is seldom formed. Even polymerized film occurs, the relevant film is sputtered and turned into radicals of CF, CF₂, or CF₃, etc. Then, the radicals fly out into a gaseous phase and become etchants.

It can be considered that, with the effect of this etchant generation and an acceleration of electrons at the top plate, i.e., opposite electrode, etching of submicronic hole pattern was carried out without any etch-stop under the condition in that the etch-stop had arisen in the system with the conventional structure. Further, it has been impossible with the conventional apparatus to perform etching of 15 μm or more in depth due to exhaustion of the mask. However, it is now possible with the present invention.

In the example described above, the capacity of 100 pF is used as the capacity of the capacitor 41 that is used for branching the radio frequency power to be applied to the counter electrode 37. However, it is required to properly select the value of capacity in accordance with values of the radio frequency power used for generating plasma, the bias radio frequency power for the substrate mounting electrode.

In the embodiment shown in FIG. 4, the carbonic material is used as a material for the inner wall of the top plate 37, however, silicone, a silicone compound or silicone composite, alternatively, a compound or composite of silicone and carbonic material can be used instead.

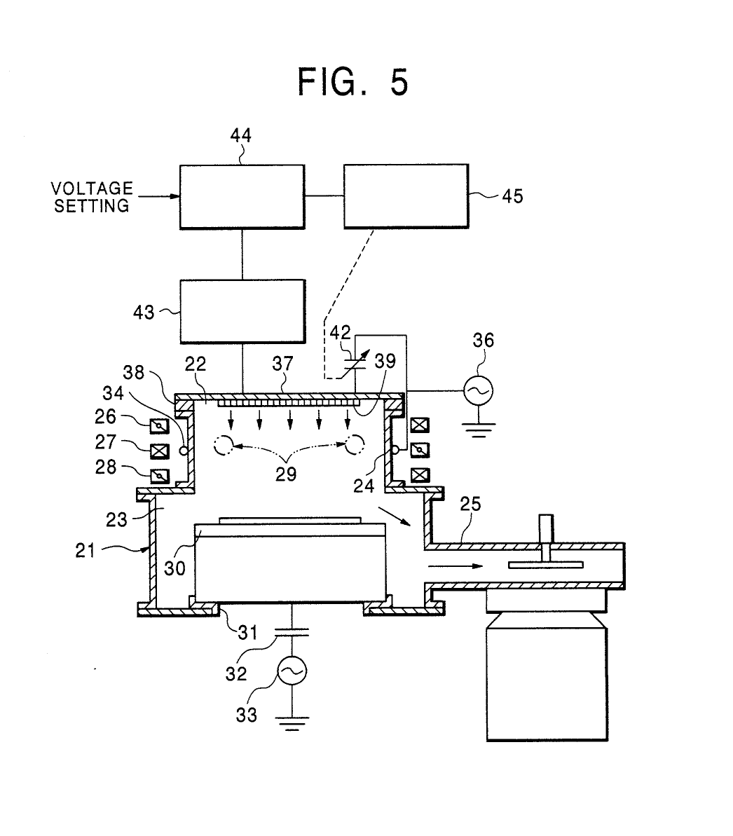

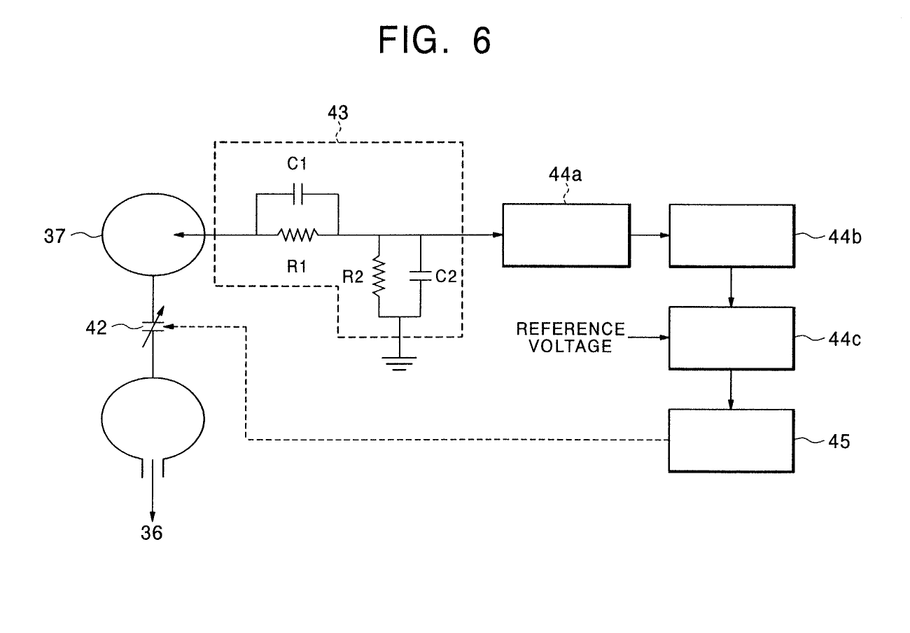

FIGS. 5 and 6 illustrate an etching apparatus according to another embodiment of the present invention that uses a two-frequency type discharge system. In FIG. 5, the same constituting elements as those of that shown in FIG. 4 are indicated by the same reference numerals.

The etching apparatus illustrated in FIG. 5 comprises a vacuum chamber 21. An upper section of the chamber 21 is a plasma generating section 22 that is defined by a dielectric cylindrical wall 24. A lower section of the chamber 21 is a substrate mounting electrode section 23. An exhaust port 25 is provided in the substrate mounting electrode section 23. Three magnetic coils 26, 27 and 28 are provided outside the wall (dielectric wall) 24 of the plasma generating section 22. An annular magnetic neutral line or loop 29 is generated in the plasma generating section 22 by three the magnetic coils 26, 27 and 28.

A substrate mounting electrode 30 is provided in parallel to a plane formed by the magnetic neutral loop 29 and is disposed in the substrate mounting electrode section 23 with an insulating member 31 interposed. The substrate mounting electrode 30 is connected through a blocking capacitor 32 to a radio frequency power supply 33 that applies a radio frequency bias power thereto. The substrate mounting electrode 30 is a floating electrode in terms of potential and has a negative bias potential.

A radio frequency antenna coil 34 used for generating plasma has a single turn and is disposed between the intermediate magnetic coil 27 and the outside of the dielectric wall 24. The radio frequency antenna coil 34 is connected directly to a radio frequency power source 36 for producing an inductive coupling discharge. The radio frequency antenna coil 34 is configured to apply an alternating electric field along the magnetic neutral loop 29 generated by the magnetic coils 26, 27 and 28 so as to generate discharge plasma on the relevant magnetic neutral loop 29.

A ground electrode provided at the position opposite to the substrate mounting electrode 30 is configured to be a top plate 37 that is an opposite electrode whose potential is turned into a floating state by a dielectric material. The top plate 37 is bonded in a sealed manner to an upper flange of the dielectric wall 24 with an insulator 38 interposed therebetween. The top plate 37 may be formed using carbonic materials or silicone, or a compound of these materials as the materials for its inner wall.

In the plasma generating section 22, there is provided a gas inlet 39 through which etching gas is introduced into the vacuum chamber 21. Although it is not shown, the gas inlet 39 is connected to a supply source of etching gas through a gas supply path and a gas flow rate controller that controls quantity of etching gas flow.

Further, in the illustrated etching apparatus, the feed line extending from the radio frequency power source 36 to the antenna coil 34 is branched as shown at 40. The shunt 40 may be provided at an arbitrary position on the feed line between the radio frequency power supply 36 used for generating plasma and the radio frequency antenna coil 34 that generates induced discharge, so as to branch radio frequency power for induced discharge. Thus, a part of the radio frequency power is applied to the top plate 37 that is an opposite electrode through a variable capacitor 42, thereby making the opposite electrode generate a self-bias.

In the embodiment of the invention, as shown in FIG. 5, the radio frequency power from the RF power source 36 is branched and applied to the opposite electrode 37 through the variable capacitor 42. To the variable capacitor 42 is incorporated a control circuit shown in FIG. 6. The control circuit comprises a radio frequency voltage measuring circuit 43 that is connected to the opposite electrode 37 for measuring voltage to be applied to the opposite electrode from the radio frequency power supply 36 through the shunt 40. As shown in FIG. 6, the measuring circuit 43 includes two capacitors C1 and C2 and two resistors R1 and R2.

The control circuit further comprises a detector and DC differential amplifier circuit 44 that is connected to the measuring circuit 43. As shown In FIG. 6 the detector and DC differential amplifier circuit 44 includes a buffer amplifier 44a that is connected to the opposite electrode 37, a detector circuit 44b that is connected to an output of the buffer amplifier 44a and converts the radio frequency into a direct current, and a comparator and controller circuit 44c that compares the output voltage from the detector circuit 44b with a predetermined reference voltage and detects the difference between the output voltage from the detector circuit 44b and the reference voltage. The control circuit further comprises a motor driving circuit 45 that is connected to the detector and DC differential amplifier circuit 44 and drives a variable capacitor 42 so that the measured voltage becomes to be equal to the predetermined value.

The etching apparatus according to the embodiment of the invention, which is shown in FIGS. 5 and 6 is configured as the above, has a simple structure and is inexpensive. Furthermore, the etching apparatus is capable of forming highly effective plasma without involving any problem such that the electric fields to be applied interfere with each other. In addition, the radio frequency voltage within a predetermined value can be applied to the top plate that is a counter electrode. Therefore, the film stuck to the top plate can be eliminated efficiently by a sputtering processing. Furthermore, the resistance of the mask can be improved and a satisfactory etching rate can be achieved without restricting an etching processing.

According to the experiment carried out by the inventors, the following has been found. That is, in the case of using the radio frequency power supply 36 of 13.56 MHz, when the voltage Vdc to be applied to the top plate 37 is set at −500 V or less (at 500 V or more in an absolute value), no film sticks to the top plate 37. In this case, if the value of Vdc is too large, the top plate is sputtered excessively. Therefore, it is desirable to set the voltage at about −500V. On the other hand, when it is intended to improve the etching resistance of the mask by etching a material for the top plate by a sputtering processing so as to deposit the relevant material on the substrate, the voltage Vdc on the top plate is to be set at −500V or less (at 500V or more in an absolute value). In the case where a film can be stuck to the top plate as long as the stuck film does not generate dust, the voltage Vdc on the top plate may be set at −500V or more (in the range of −500V to −50V).

In regard to the system in that the feed line of the radio frequency power supply 36 connected to the antenna coil 34 is branched so as to branch the radio frequency power and a part of the radio frequency electric power is branched and applied to the a Faraday shield-type (or electrostatic field shield-type) floating electrode that is disposed inside the antenna coil 34 through the variable capacitor 42, the system can be constructed in the manner similar to the system that uses the top plate as a floating electrode. Accordingly, the similar etching processing can be executed with this system. The Faraday shield-type floating electrode and the like can be disposed inside the radio frequency antenna coil 34. However, for the case where a Faraday shield is disposed inside the radio frequency antenna coil 34 and outside the dielectric wall 25 that is the wall of the plasma generating section 22 of the vacuum chamber 21, a dielectric body is interposed between the plasma and the Faraday shield. Therefore, a film cannot be prevented from sticking, unless the potential on the surface of the dielectric wall is set at −500V. Accordingly, in the case of disposing the Faraday shield outside the dielectric wall, it is necessary to further reduce the potential of the Faraday shield. (It is necessary to increase the absolute value.) In the case of disposing the Faraday shield inside the vacuum chamber so as to bring the Faraday shield into contact with the plasma, the potential of the surface of the Faraday shield is set at −500V. Then, a film seldom sticks. The difference between phenomena is depending on the thickness of the dielectric.

The aforementioned Faraday shield is a well-known one. The Faraday shield is, for example, a metal plate in which a plurality of slits is provided in parallel to each other and an antenna coil is provided at right angles to the slits in the middle of the slits in its longitudinal direction. At both ends of the slits in the longitudinal direction, there are provided metal edges, which set the potential of the rectangular metal plate at a uniform value. An electrostatic field of the antenna coil is shielded by means of the metal plate. However, its inductive magnetic field is not shielded. This inductive magnetic field comes into the plasma and thus forms an inductive electric field. The width of each slit can be designed arbitrarily in accordance with purposes. Although the width of about 0.5 to 10 mm is adopted, the slits of 1 to 2 mm in width are enough, in general. If the width of the slit is too wide, the electrostatic field penetrates thereto, which is not preferable. The width of the slit should be up to 2 mm.

Next, an etching processing was performed with use of a NLD etching apparatus shown in FIGS. 5 and 6.

The etching processing was performed under the following conditions: with use of: the power of radio frequency power supply 36 (13.56 MHz) for generating plasma being 1.2 kW; the power of the radio frequency power supply 30 (12.56 MHz) for substrate bias being 0.5 kW; the capacity for the variable capacitor 42 being 200 pF; Ar 90 scan and C₄F₈ 10 scam (10%) being introduced into the vacuum chamber 21; and the pressure in the vacuum chamber 21 being in 3 mTorr. Then, the etching rate of 600 nm/min. and the selectivity of 25 (ratio of the etching rate for SiO₂ to the etching rate for poly-Si) were acquired with respect to a thermal oxide SiO₂ film with poly-Si used as a mask.

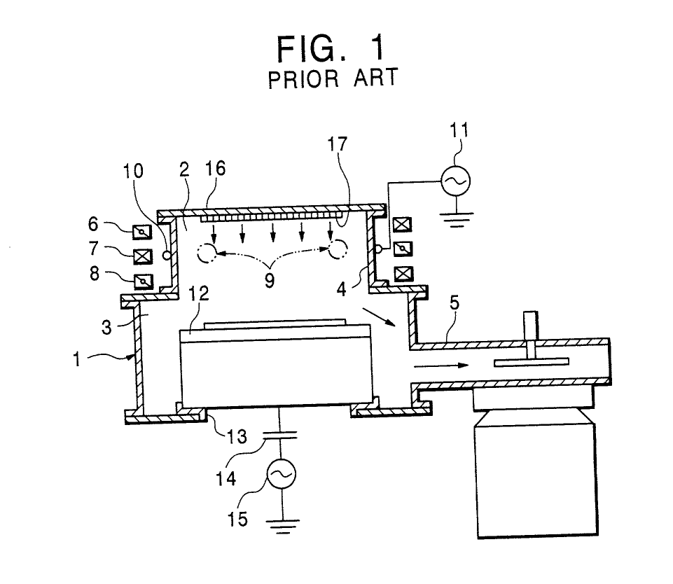

In comparison with the result of etching processing using the conventionally constructed system (FIG. 1) under the same condition, the selectivity was improved by 2.5 times at the substantially same etching rate, although there was a certain amount of dispersion in accordance with the widths of a pattern.

In the embodiment shown in the drawing, the example has been described with use of the NLD etching apparatus. However, it is obvious that the similar effect can be obtained with respect to the NLD plasma CVD system. It is also obvious that the similar effect can be obtained with respect to the ICP etching apparatus and ICP CVD system.

As described above, in the plasma processing apparatus according to one aspect of the invention, the ground electrode provided at the position opposite to the substrate mounting electrode is configured to be a counter electrode whose potential being in a floating state by the dielectric body, and radio frequency power is shunted at an arbitrary position of a feed line to the radio frequency antenna coil that generates inductively coupled discharge plasma into the counter electrode through the capacitor so as to share a part of the radio frequency power used for inductively coupled discharge plasma with the counter electrode, so that a self-bias is generated in the counter electrode. Therefore, it is not necessary to provide a radio frequency power supply separately for the counter electrode. As a result, the construction of the system can be simplified. Furthermore, the problem concerning interference can be solved. In addition, the similar effect can be obtained with use of a single coil, triple coils or a serial-turned antenna, instead of the parallel coils.

Further, in the case where the radio frequency antenna coil that generates inductively coupled discharge plasma is constituted by two paralleled coils, a satisfactory vertical etching property can be obtained and thus selectivity can be improved.

According to the invention, radio frequency having a predetermined voltage value can be applied to the counter (opposite) electrode. Thus, it is possible to improve resistance of a mask and achieve a satisfactory etching rate.

On the other hand, materials generated by discomposing gas by means of plasma stick to the wall. However, a counter electrode is provided above the substrate and applied with radio frequency power. In this case, ions included in plasma sputter continuously the surface of the counter electrode. Therefore, a film is restrained from sticking to the wall and dust is prevented from occurring. Furthermore, the film that stuck to the top plate, i.e. the inner surface of the counter electrode and polymerized is sputtered, thereby generating an etchant.

Further, according to the invention, the counter electrode is applied with radio frequency power, thereby generating a negative bias in the counter electrode. Therefore, the counter electrode is always bombarded by positive ions. As a result, in comparison with the conventional system having the structure in that the top plate is used as a ground electrode, a film is restrained from sticking to the top plate and thus dust is prevented from generating from the top plate. Furthermore, a material such as SiFx, WFx or the like is generated with use of the top plate made of metal such as Si, WSi or the like, and the generated material is deposited on the mask. Then, it is possible to suppress consumption of the mask and thus it becomes possible to perform deep-trench etching.

What is claimed is:

1. A plasma processing apparatus in which gas is introduced into a vacuum chamber so as to form inductively coupled discharge plasma by means of at least one radio frequency antenna coil to which a first radio frequency power source is connected, and a substrate mounting electrode is supplied with a radio frequency power from a second radio frequency power source connected thereto so as to generate a negative self-bias in the substrate mounting electrode, wherein a ground electrode is provided at the position opposite to the substrate mounting electrode and is arranged as an opposite electrode whose potential is kept in a floating state by a dielectric material, and a shunt is provided on a feed line between the radio frequency antenna coil and the first radio frequency power source for applying a part of radio frequency power from the radio frequency power source to the opposite electrode through a capacitor connected to the shunt, thereby generating a self-bias in the opposite electrode.

2. The plasma processing system as claimed in claim 1, wherein the radio frequency antenna coil for generating inductive discharge comprises multiple parallel coils.

3. The plasma processing system as claimed in claim 1, wherein the opposite electrode is constituted by a top plate that is located at the upper portion of the vacuum chamber formed of a dielectric material.

4. A plasma processing apparatus comprising:
a vacuum chamber having a plasma generating section in an upper portion thereof and a substrate mounting electrode section in a lower portion thereof;
at least one radio frequency antenna coil for generating plasma provided outside a dielectric wall of the plasma generating section, the antenna coil being connected to a radio frequency power source;
a substrate mounting electrode disposed in the substrate mounting electrode section, the substrate mounting electrode being connected to another radio frequency power source and applied with radio frequency bias power; and
an opposite electrode disposed in the plasma generating section in a manner of opposing to the substrate mounting electrode,
wherein
the opposite electrode is a floating electrode, which is bonded in a sealed manner to an upper flange of the wall of the plasma generating section with an insulator interposed therebetween and whose potential is in a floating state,
a shunt is provided on a feed line between the antenna coil and the radio frequency power source connected to the antenna coil for applying a part of radio frequency power to the floating electrode through a variable capacitor provided on the shunt, and
control means is provided for monitoring radio frequency voltage to be applied to the floating electrode and controlling the radio frequency voltage uniformly.

5. The plasma processing system as claimed in claim 4, wherein the apparatus further comprises at least one magnetic coil provided outside the antenna coil, an alternating electric field is applied along an annular magnetic neutral line or loop formed in a plasma generating section by means of the magnetic coil, thereby making the magnetic neutral loop generate discharge plasma.

6. The plasma processing system as claimed in claim 4, wherein
the control means includes;
a radio frequency voltage measuring circuit that measures voltage to be applied from the radio frequency power source to a floating electrode;
a DC differential amplifier circuit that detects the difference between the measured voltage and a predetermined voltage value and is provided with a detection circuit that converts the radio frequency into direct current; and
a motor driving circuit that drives the variable capacitor in such a manner that the measured voltage becomes to be equal to the predetermined voltage value,
the voltage measuring circuit is connected to the floating electrode,
the detection and DC differential amplifier circuit is connected to the voltage measuring circuit,
the motor driving circuit is incorporated in the variable capacitor and is connected to the detection and DC differential amplifier circuit, and
the variable capacitor controls radio frequency voltage uniformly.

7. A plasma processing apparatus comprising:
a vacuum chamber having a plasma generating section in an upper portion thereof and a substrate mounting electrode section in a lower portion thereof;
at least one radio frequency antenna coil for generating plasma provided outside a dielectric wall of the plasma generating section, the antenna coil being connected to a radio frequency power source; and
a substrate mounting electrode disposed in the substrate mounting electrode section, the substrate mounting electrode being connected to another radio frequency power source and applied with radio frequency bias power,
wherein
a Faraday shield or a electrostatic field shield type floating electrode is provided inside the antenna coil,
a shunt is provided on a feed line between the antenna coil and the radio frequency power source connected to the antenna coil for applying a part of radio frequency power to the floating electrode through a variable capacitor provided on the shunt, and
control means is provided for monitoring radio frequency voltage to be applied to the floating electrode and controlling the radio frequency voltage uniformly.

8. The plasma processing system as claimed in claim 7, wherein the apparatus further comprises at least one magnetic coil provided outside the antenna coil, an alternating electric field is applied along an annular magnetic neutral line or loop formed in a plasma generating section by means of the magnetic coil, thereby making the magnetic neutral loop generate discharge plasma.

9. The plasma processing system as claimed in claim 7, wherein
the control means includes;
a radio frequency voltage measuring circuit that measures voltage to be applied from the radio frequency power source to a floating electrode;
a DC differential amplifier circuit that detects the difference between the measured voltage and a predetermined voltage value and is provided with a detection circuit that converts the radio frequency into direct current; and
a motor driving circuit that drives the variable capacitor in such a manner that the measured voltage becomes to be equal to the predetermined voltage value,
the voltage measuring circuit is connected to the floating electrode,
the detection and DC differential amplifier circuit is connected to the voltage measuring circuit,
the motor driving circuit is incorporated in the variable capacitor and is connected to the detection and DC differential amplifier circuit, and
the variable capacitor controls radio frequency voltage uniformly.
